(19) United States
(12) Patent Application Publication
(10) Pub. No.: US 2026/0052687 A1
(43) Pub. Date: Feb. 19, 2026

(54) THREE-DIMENSIONAL MEMORY DEVICES AND FABRICATING METHODS THEREOF

(71) Applicant: YANGTZE MEMORY TECHNOLOGIES CO., LTD., Wuhan (CN)

(72) Inventors: Xiaoxin Liu, Wuhan (CN); Zongliang Huo, Wuhan (CN)

(21) Appl. No.: 18/935,192

(22) Filed: Nov. 1, 2024

Related U.S. Application Data
(63) Continuation of application No. PCT/CN2024/112639, filed on Aug. 16, 2024.

(51) Int. Cl. H10B 43/27; H10B 41/27

(52) U.S. Cl. CPC H10B 43/27; H10B 41/27

(57) ABSTRACT

A disclosed memory device includes a lower structure including a first stack including interleaved lower conductive layers and first lower dielectric layers, a second stack on a lateral side of the first stack and including interleaved second lower dielectric layers and the first lower dielectric layers, and lower contact structures extending in the second stack and each being in contact with a corresponding one of the lower conductive layers of the first stack; and an upper structure on the lower structure including a staircase structure comprising interleaved upper conductive layers and upper dielectric layers on the first stack, a dielectric filling structure on the second stack, stair contacts on the staircase structure, each stair contact being in contact with a corresponding one of the upper conductive layers, and upper contact structures each extending through the dielectric filling structure and in contact with a corresponding one of the lower contact structures.

### CROSS-REFERENCE TO RELATED APPLICATIONS

This application is a continuation of International Application No. PCT/CN2024/112639, filed on Aug. 16, 2024, which is hereby incorporated by reference in its entirety.

### TECHNICAL FIELD

The present disclosure generally relates to the field of semiconductor technology, and more particularly, to three-dimensional (3D) memory devices, and fabricating methods for forming three-dimensional (3D) memory devices.

### BACKGROUND

Planar memory cells are scaled to smaller sizes by improving process technology, circuit design, programming algorithm, and fabrication process. However, as feature sizes of the memory cells approach a lower limit, planar process and fabrication techniques become challenging and costly. As such, memory density for planar memory cells approaches an upper limit. A three-dimensional (3D) memory architecture can address the density limitation in planar memory cells. As semiconductor technology advances, 3D memory devices, such as 3D NAND memory devices, keep reducing costs and increasing capacity.

### SUMMARY

Three-dimensional (3D) memory devices and fabricating methods thereof are disclosed herein.

One aspect of the present disclosure provides a semiconductor device comprising a lower structure and an upper structure on the lower structure. The lower structure comprises a first stack comprising interleaved lower conductive layers and first lower dielectric layers, a second stack on a lateral side of the first stack, and comprising interleaved second lower dielectric layers and the first lower dielectric layers, and lower contact structures extending in the second stack and each being in contact with a corresponding one of the lower conductive layers of the first stack. The upper structure on the lower structure comprises a staircase structure comprising interleaved upper conductive layers and upper dielectric layers on the first stack, a dielectric filling structure on the second stack, stair contacts on the staircase structure, each stair contact being in contact with a corresponding one of the upper conductive layers, and upper contact structures each extending through the dielectric filling structure and in contact with a corresponding one of the lower contact structures.

In some implementations, each lower contact structure comprises a vertical conductive structure vertically extending in the second stack, and a lateral conductive structure at a bottom of the vertical conductive structure and laterally in contact with the corresponding one of the lower conductive layers of the first stack.

In some implementations, each lower contact structure further comprises a spacer layer laterally surrounding the vertical conductive structure to separate the vertical conductive structure from the second stack, and a filling layer surrounded by the vertical conductive structure and the lateral conductive structure.

In some implementations, the semiconductor device further comprises a first slit structure and a second slit structure extending parallel along a first lateral direction in the upper structure and the lower structure, wherein the first stack comprises a first portion adjacent to the first slit structure and a second portion adjacent to the second slit structure, and the second stack is located between the first portion and the second portion of the first stack along a second lateral direction perpendicular to the first lateral direction.

In some implementations, the staircase structure comprises: a first staircase adjacent to the first slit structure and comprises odd numbers of stairs, and a second staircase adjacent to the second slit structure and comprises even numbers of stairs, wherein the dielectric filling structure is located between the first staircase and the second staircase along the second lateral direction.

In some implementations, the lower contact structures are aligned into two rows between the first slit structure and the second slit structure; each of the two rows of the lower contact structures extends along the first lateral direction; and the two rows of the lower contact structures are arranged in a staggered manner in the second lateral direction.

In some implementations, a first row of the lower contact structures are located adjacent to the first portion of the first stack; each lower contact structure in the first row is in contact with a corresponding odd layer of the lower conductive layers in the first portion of the first stack; a second row of the lower contact structures are located adjacent to the second portion of the first stack; and each lower contact structure in the second row is in contact with a corresponding even layer of the lower conductive layers in the second portion of the first stack.

In some implementations, the semiconductor device further comprises channel structures vertically extending in the upper structure and the lower structure in an array region, and dummy channel structures vertically extending in the upper structure and the lower structure in a contact region.

In some implementations, the first slit structure and the second slit structure have a first width along the second lateral direction in the array region and a second width different from the first width in the contact region.

In some implementations, the stair contacts comprise: a first group of stair contacts on the first staircase and in contact with the upper conductive layers of the odd numbers of stairs; and a second group of stair contacts on the second staircase and in contact with the upper conductive layers of the even numbers of stairs.

Another aspect of the present disclosure provides a memory system, comprising: a memory device, comprising: a lower structure comprising: a first stack comprising interleaved lower conductive layers and first lower dielectric layers, a second stack on a lateral side of the first stack, and comprising interleaved second lower dielectric layers and the first lower dielectric layers, and lower contact structures extending in the second stack and each being in contact with a corresponding one of the lower conductive layers of the first stack; and an upper structure on the lower structure, comprising: a staircase structure comprising interleaved upper conductive layers and upper dielectric layers on the first stack, a dielectric filling structure on the second stack, stair contacts on the staircase structure, each stair contact being in contact with a corresponding one of the upper conductive layers, and upper contact structures each extending through the dielectric filling structure and in contact with a corresponding one of the lower contact structures; and a memory controller coupled with the memory device and configured to control the memory device.

Another aspect of the present disclosure provides a method of forming semiconductor device, comprising: forming a lower structure comprising: forming a first stack comprising interleaved lower conductive layers and first lower dielectric layers, forming a second stack comprising interleaved second lower dielectric layers and the first lower dielectric layers, and forming lower contact structures in the second stack, each lower contact structure being in contact with a corresponding one of the lower conductive layers of the first stack; forming an upper structure comprising: forming interleaved upper conductive layers and upper dielectric layers on the lower structure, forming a staircase structure on the first stack, forming a dielectric filling structure on the second stack, and forming upper contact structures each extending through the dielectric filling structure and in contact with a corresponding one of the lower contact structures.

In some implementations, forming the upper structure further comprises: forming stair contacts on the staircase structure, each stair contact being in contact with a corresponding one of the upper conductive layers; wherein the stair contacts and the upper contact structures are formed simultaneously in a same process.

In some implementations, forming each lower contact structure comprises: forming an opening in the second stack and stopping at one second lower dielectric layer; removing a portion of the at one second lower dielectric layer and forming an lateral conductive structure; forming a spacer layer on a sidewall of the opening and the lateral conductive structure; removing a bottom portion of the spacer layer to expose the lateral conductive structure; and forming a vertical conductive structure in the opening and in contact with the lateral conductive structure.

In some implementations, the method further comprises forming a first slit and a second slit extending parallel along a first lateral direction and vertically in the upper structure and the lower structure; and replacing portions of the second lower dielectric layers adjacent to the first slit and the second slit by the lower conductive layers to form the first stack.

In some implementations, forming the lower contact structures comprises: forming rows of the lower contact structures, each row of the lower contact structures extending along the first lateral direction, wherein the rows of the lower contact structures are arranged in a staggered manner in a second lateral direction perpendicular to the first lateral direction.

In some implementations, forming the first slit and the second slit comprises: forming the first slit and the second slit to sandwich two rows of the lower contact structures between the first slit and the second slit in the second lateral direction.

In some implementations, replacing portions of the second lower dielectric layers comprises: replacing the portions of the second lower dielectric layers adjacent to the first slit to form a first portion of the first stack, such that odd layers of the lower conductive layers in the first portion are in contact with the lateral conductive structures of a first row of the two rows of the lower contact structures, respectively; and replacing the portions of the second lower dielectric layers adjacent to the second slit to form a second portion of the first stack, such that even layers of the lower conductive layers in the second portion are in contact with the lateral conductive structures of a second row of the two rows of the lower contact structures.

In some implementations, the method further comprises forming channel structures vertically extending in the upper structure and the lower structure in an array region, and forming dummy channel structures vertically extending in the upper structure and the lower structure in a contact region.

In some implementations, the method further comprises filling portions of the first slit and the second slit in the contact region, replacing the second lower dielectric layers of the lower structure in the array region with the lower conductive layers in the array region, and replacing upper sacrificial layers of the upper structure in the array region with the upper conductive layers in the array region.

In some implementations, the method further comprises forming a first slit structure in the first slit and a second slit structure in the second slit, wherein the first slit structure and the second slit structure have a first width along the second lateral direction in the array region and a second width different from the first width in the contact region.

Other aspects of the present disclosure can be understood by those skilled in the art in light of the description, the claims, and the drawings of the present disclosure.

### BRIEF DESCRIPTION OF THE DRAWINGS

The accompanying drawings, which are incorporated herein and form a part of the specification, illustrate implementations of the present disclosure and, together with the description, further serve to explain the principles of the present disclosure and to enable a person skilled in the pertinent art to make and use the present disclosure.

FIG. 1 illustrates a block diagram of a system having a memory device, according to some aspects of the present disclosure.

FIG. 2A illustrates a diagram of an exemplary memory card having a memory device, according to some aspects of the present disclosure.

FIG. 2B illustrates a diagram of an exemplary solid-state drive (SSD) having a memory, according to some aspects of the present disclosure.

FIG. 3 illustrates a planar view of a portion of a 3D memory device, according to some aspects of the present disclosure.

FIG. 4 illustrates an enlarged planar view of a portion of a 3D memory device, according to some aspects of the present disclosure.

FIGS. 5A-5C illustrate cross-sectional views of a portion of a 3D memory device, according to some aspects of the present disclosure.

FIG. 6 illustrates a flow diagram of a method for forming a 3D memory device, according to some aspects of the present disclosure.

FIGS. 7A-7B, 8A-8B, 9A-9B, and 10A-10B illustrate schematics of a 3D memory device at certain fabricating stages of the method shown in FIG. 6 in a cross-sectional view according to various aspects of the present disclosure.

The present disclosure will be described with reference to the accompanying drawings.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one implementation,” “an implementation,” “an example implementation,” “some implementations,” etc., indicate that the implementation described may include a particular feature, structure, or characteristic, but every implementation may not necessarily include the particular feature, structure, or characteristic. Moreover, such phrases do not necessarily refer to the same implementation. Further, when a particular feature, structure or characteristic is described in connection with an implementation, it would be within the knowledge of a person skilled in the pertinent art to effect such feature, structure or characteristic in connection with other implementations whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of lateral planes between, or at, a top surface and a bottom surface of the continuous structure. A layer can extend laterally, vertically, and/or along a tapered surface. A substrate can be a layer, can include one or more layers therein, and/or can have one or more layer thereupon, thereabove, and/or therebelow. A layer can include multiple layers. For example, an interconnection layer can include one or more conductor and contact layers (in which contacts, interconnect lines, and/or vias are formed) and one or more dielectric layers.

As used herein, the term “nominal/nominally” refers to a desired, or target, value of a characteristic or parameter for a component or a process operation, set during the design phase of a product or a process, together with a range of values above and/or below the desired value. The range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

As used herein, the term “3D memory device” refers to a semiconductor device with vertically-oriented strings of memory cell transistors (i.e., region herein as “memory strings,” such as NAND strings) on a laterally-oriented substrate so that the memory strings extend in the vertical direction with respect to the substrate. As used herein, the term “vertical/vertically” means nominally perpendicular to a lateral surface of a substrate.

As described above, 3D NAND memory devices keep reducing costs and increasing capacity by compressing the density of memory cells in the horizontal plane. In some 3D NAND memory devices, memory cells for storing data are vertically stacked through a stack structure (e.g., a memory stack) in vertical channel structures. 3D memory devices usually include staircase structures formed on one or more sides (edges), or at the center, of the stacked storage structure for purposes, such as word line pick-up/fan-out, using word line contacts landed onto different steps/levels of a staircase structure. Dummy channel structures are usually formed through the memory stack in regions outside of the core array region in which the channel structures of 3D NAND memory devices are formed, such as staircase regions having the staircase structures, to provide mechanical support to the stack structure, in particular, during the gate replacement process that temporarily removes some layers of the stack structure through slit openings across the core array region and staircase regions of the stack structure.

The integration of the various structures, such as dummy channel structures, word line contacts, staircase structures, slit openings, etc., from both the device design perspective and the fabrication process perspective, has become more and more challenging as the memory cell density of the 3D NAND memory devices continues increasing.

Contact structures (e.g., word line pick-up structures) are introduced to achieve the word line pick-up/fan-out functions without using staircase structures and word line contacts. For example, the two structures—staircase structure and word line contact, as well as their separate processes, can be merged into a single contact structure in one process, thereby reducing the manufacturing cost and simplifying the process. Moreover, by replacing staircase structures and word line contacts with contact structures, the scope of the gate replacement process can be reduced, such that at least some of the dummy channel structures can be eliminated as well to further reduce the cost and simplify the process.

On the other hand, multi-deck stacking is a trend in the 3D NAND memory structure design, but channel current is still a problem for super high-level boards. Moreover, it is a challenge to etch contact holes with a high Depth-to-Diameter Ratio in a multi-deck stacking structure. In addition, the channel hole arrangement in the bit line direction will be a major design concern in the future.

To address one or more of the aforementioned issues, the present disclosure introduces a new integration structure, in which a lower memory deck can have contact structures while an upper memory deck can have staircase structures. Specifically, the lower memory deck can comprise a first stack comprising interleaved lower conductive layers and first lower dielectric layers, a second stack on a lateral side of the first stack, and comprising interleaved second lower dielectric layers and the first lower dielectric layers, and lower contact structures extending in the second stack and each being in contact with a corresponding one of the lower conductive layers of the first stack. The upper memory deck can comprise a staircase structure comprising interleaved upper conductive layers and upper dielectric layers on the first stack, a dielectric filling structure on the second stack, stair contacts on the staircase structure, each stair contact being in contact with a corresponding one of the upper conductive layers, and upper contact structures each extending through the dielectric filling structure and in contact with a corresponding one of the lower contact structures. The disclosed integration design can allow more channel structure arranged in the bit line direction, thereby significantly increasing the memory density.

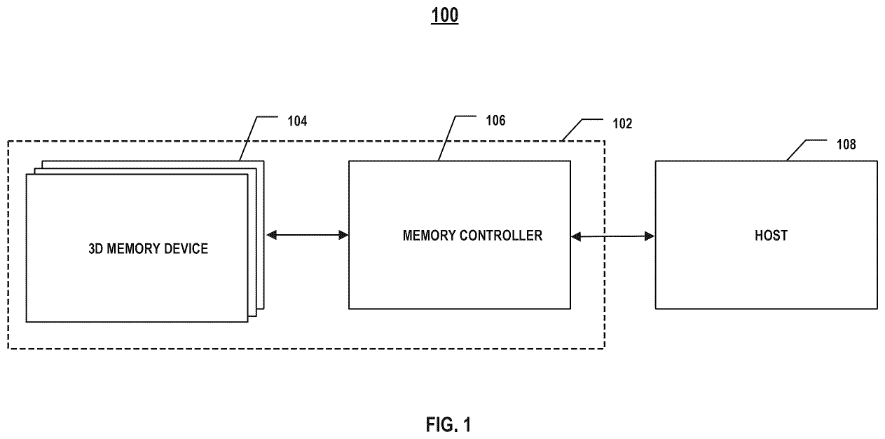

FIG. 1 illustrates a block diagram of a system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 1, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive the data to or from memory devices 104.

Memory device 104 can be any memory devices disclosed herein, such as a NAND Flash memory device. Consistent with the scope of the present disclosure, memory controller 106 may control the multi-pass programming on memory device 104 such that an NGS operation is enabled on all memory cells, even those passed the respective verify operations, in a non-last programming pass of the multi-pass programming. The peripheral circuits, such as the word line drivers, may apply a low voltage, e.g., ground (GND) voltage, on the DSGs of each memory string coupled to the selected word line, and may apply a low or negative voltage on the selected word line to enable an NGS operation on all memory cells coupled to the selected word line during a non-last programming pass.

Memory controller 106 is coupled to memory device 104 and host 108 and is configured to control memory device 104, according to some implementations. Memory controller 106 can manage the data stored in memory device 104 and communicate with host 108. In some implementations, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 106 is designed for operating in a high duty-cycle environment SSDs or embedded multi-media-cards (eMMCs) used as data storage for mobile devices, such as smartphones, tablets, laptop computers, etc., and enterprise storage arrays. Memory controller 106 can be configured to control operations of memory device 104, such as read, erase, and program operations. Memory controller 106 can also be configured to manage various functions with respect to the data stored or to be stored in memory device 104 including, but not limited to bad-block management, garbage collection, logical-to-physical address conversion, wear leveling, etc. In some implementations, memory controller 106 is further configured to process error correction codes (ECCs) with respect to the data read from or written to memory device 104. Any other suitable functions may be performed by memory controller 106 as well, for example, programming memory device 104. Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

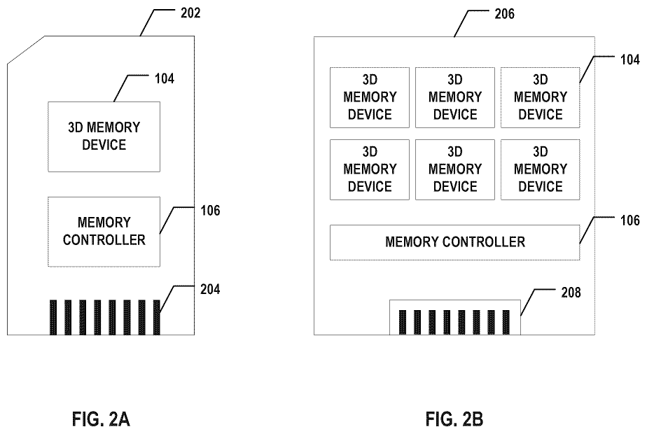

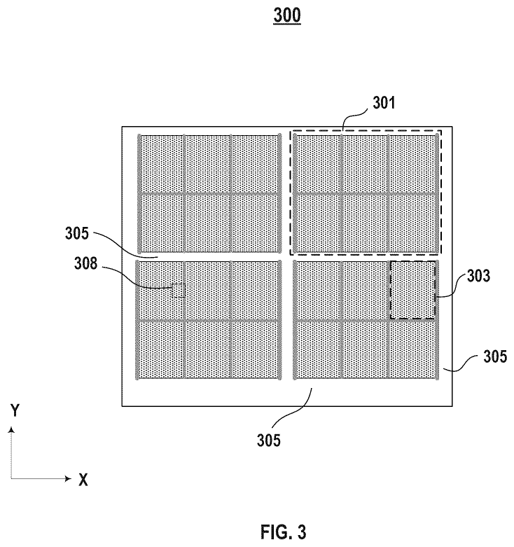

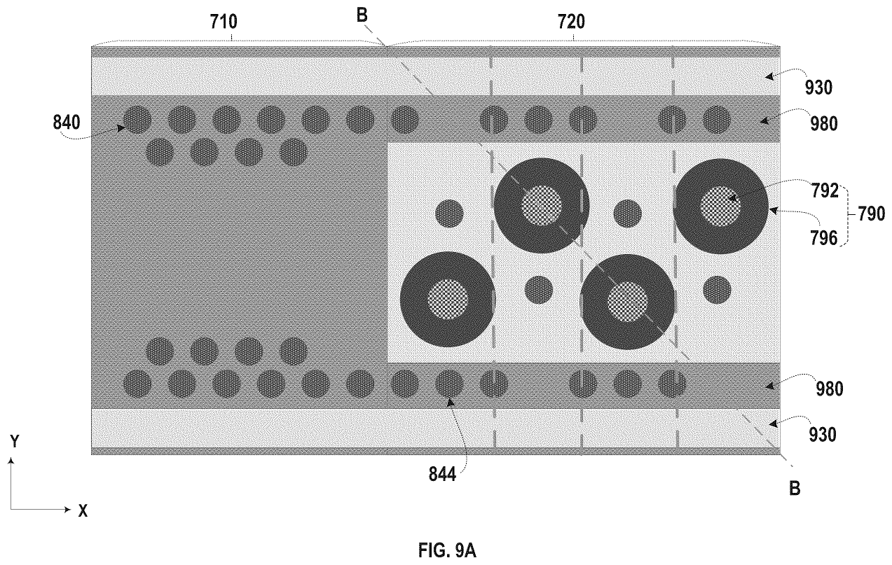

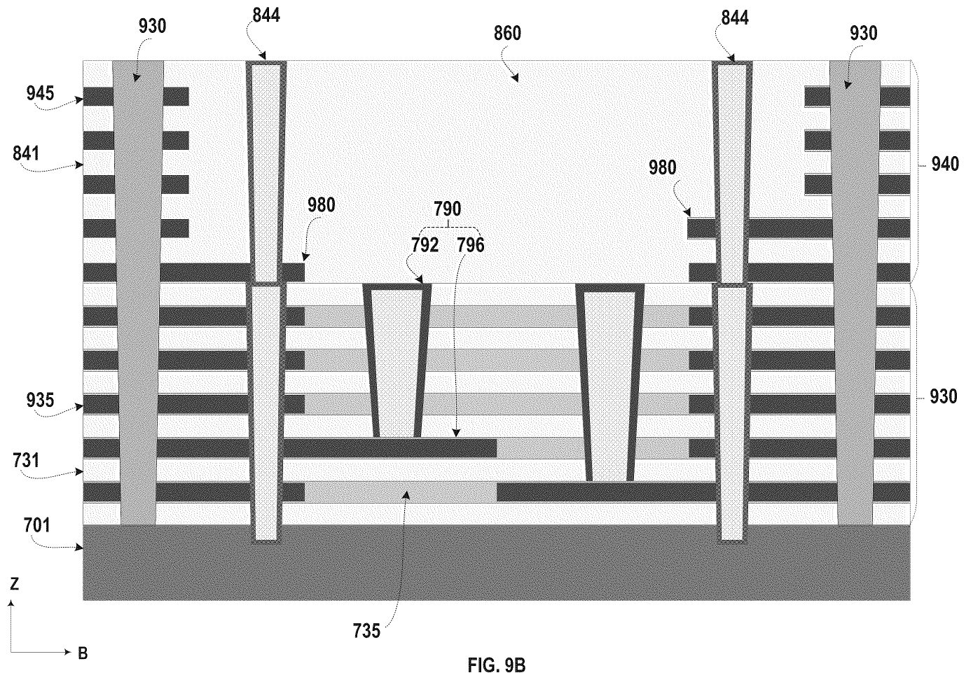

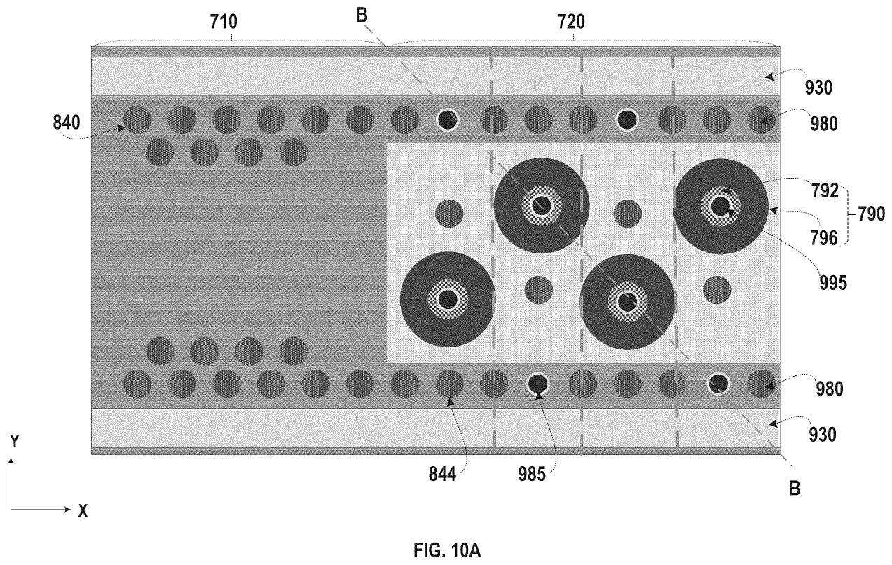

Memory controller 106 and one or more memory devices 104 can be integrated into various types of storage devices, for example, be included in the same package, such as a universal Flash storage (UFS) package or an eMMC package. That is, memory system 102 can be implemented and packaged into different types of end electronic products. In one example as shown in FIG. 2A, memory controller 106 and a single memory device 104 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 204 coupling memory card 202 with a host (e.g., host 108 in FIG. 9). In another example as shown in FIG. 2B, memory controller 106 and multiple memory devices 104 may be integrated into an SSD 206. SSD 206 can further include an SSD connector 208 coupling SSD 206 with a host (e.g., host 108 in FIG. 9). In some implementations, the storage capacity and/or the operation speed of SSD 206 is greater than those of memory card 202.

FIG. 3 illustrates a planar view of a 3D memory device 300, according to some implementations of the present disclosure. 3D memory device 300 can be a memory chip (package), a memory chip or any portion of a memory chip, and can include one or more memory planes 301, each of which can include a plurality of memory blocks 303. Identical and concurrent operations can take place at each memory plane 301. Memory block 303, which can be megabytes (MB) in size, can be the smallest size to carry out erase operations. As shown in FIG. 3, 3D memory device 300 includes four memory planes 301 and each memory plane 301 includes six memory blocks 303.

Each memory block 303 can include a plurality of memory cells, where each memory cell can be addressed through interconnections such as bit lines and word lines. The bit lines and word lines can be laid out perpendicularly (e.g., in rows and columns, respectively), forming an array of metal lines. In FIG. 3, the direction of word lines is labeled as X-direction, and the direction of bit lines is labeled as Y-direction. In this disclosure, memory block 303 is also referred to as a “memory array” or “array.” The memory array is the core area in a memory device, performing storage functions.

3D memory device 300 can include a periphery region 305, an area surrounding memory planes 301. Periphery region 305 can contain many digital, analog, and/or mixed-signal circuits to support functions of the memory array, for example, page buffers, row and column decoders, and sense amplifiers. Peripheral circuits use active and/or passive semiconductor devices, such as transistors, diodes, capacitors, resistors, etc., as would be apparent to a person of ordinary skill in the art. It is noted that, the arrangement of memory planes 301 in 3D memory device 300 and the arrangement of memory blocks 303 in each memory plane 301 illustrated in FIG. 3 are only provided as an example, which does not limit the scope of the present disclosure.

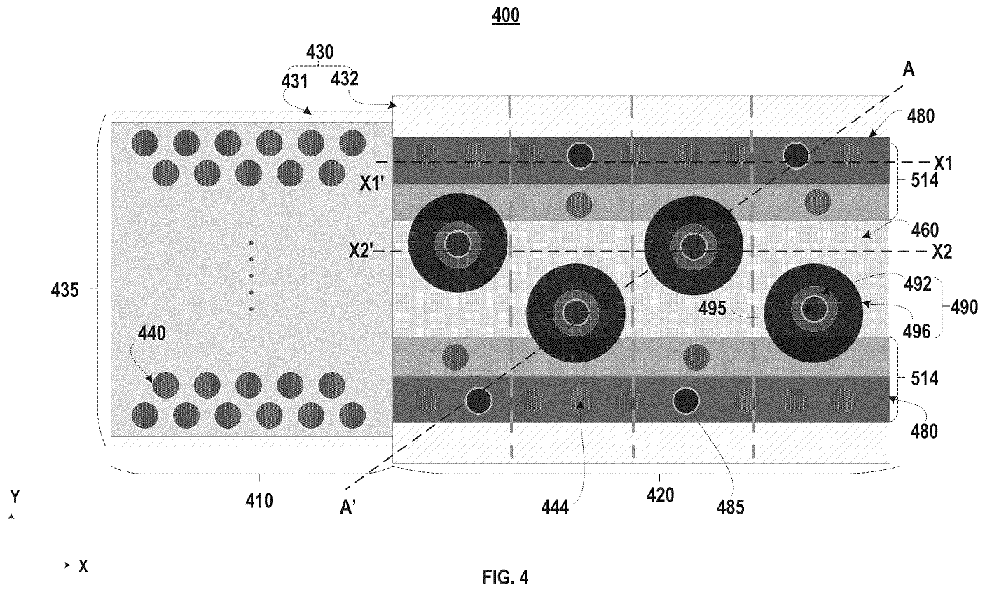

Referring to FIG. 4, a schematic diagram of a portion of a 3D memory device 400, such as region 308 of FIG. 3 is shown in an enlarged planar view, according to some implementations of the present disclosure. In some implementations, the 3D memory device 400 is a NAND Flash memory device in which memory cells are provided in the form of an array of NAND memory strings. It is noted that the X and Y axes are included in FIG. 3 to illustrate two orthogonal (perpendicular) directions in the wafer plane. The X-direction is the word line direction of the 3D memory device 400, and the Y-direction is the bit line direction of the 3D memory device 400.

As shown in FIG. 4, 3D memory device 400 can be divided into at least a core array region 410 (e.g., a first region, also referred to as “core region”) in which an array of channel structures 440 are formed, as well as a word line pick-up region 420 (e.g., a second region, also referred as “contact region”) in which word line contact structures (e.g., word line pick-up structures) are formed. Core array region 410 and word line pick-up region 420 are arranged in the X-direction (the word line direction), according to some implementations. It is understood that although one core array region 410 and one word line pick-up region 420 are illustrated in FIG. 4, multiple core array regions 410 and/or multiple word line pick-up regions 420 may be included in 3D memory device 400, for example, one word line pick-up region 420 between two core array regions 410 in the X-direction, in other examples. It is also understood that FIG. 4 only illustrates portions of core array region 410 that are adjacent to word line pick-up region 420.

In some implementations, the 3D memory device 400 is a NAND Flash memory device, and the stack structure in the core array region 410 is a stacked storage structure through which NAND memory strings are formed. The stacked storage structure in the core array region 410 can include vertically interleaved conductive layers and dielectric layers. The conductive layers and the dielectric layers can alternate in the vertical direction (the Z-direction). The conductive layers can include conductive materials including, but not limited to, tungsten (W), cobalt (Co), copper (Cu), aluminum (Al), titanium nitride (TiN), polycrystalline silicon (polysilicon), doped silicon, silicides, or any combination thereof. The dielectric layers can include dielectric materials including, but not limited to, silicon oxide, silicon nitride, silicon oxynitride, or any combination thereof.

In some implementations, the stacked storage structure can include a plurality of conductive/dielectric layer pairs stacked vertically in the Z-direction. Each channel structure 440 can extend vertically through the plurality of conductive/dielectric layer pairs. The number of conductive/dielectric layer pairs in the stacked storage structure can determine the number of memory cells in the 3D memory device 400. In some implementations, the stacked storage structure can be formed by stacking two or more decks of memory stack structures vertically in the Z-direction to increase the number of conductive/dielectric layer pairs, thereby increasing the memory density of the 3D memory device 400.

As shown, multiple gate line slit (GLS) structure 430 (also referred as “slit structure”) can extend laterally in parallel along the word line direction (i.e., X-direction) and vertically through the plurality of conductive/dielectric layer pairs. The GLS structures 430 can divide the memory array into multiple memory fingers 435, such that the conductive layers between adjacent memory fingers 435 can be separated. In some implementations, GLS structure 430 is an insulating structure that does not include any interconnects therein (i.e., not functioning as the source contact) and thus, does not introduce parasitic capacitance and leakage current with the conductive layers. In some other implementations, GLS structure 430 is a source contact further including a conductive portion (e.g., including W, polysilicon, and/or TiN) circumscribed by a slit spacer portion. As described below in detail, during the gate replacement process, the slits in which the GLS structures 430 are formed can serve as the passageway and starting point for forming the conductive layers. As a result, the GLS structures 430 are surrounded by conductive layers in either core array region 410 or word line pick-up region 420.

In some implementations, each memory finger 435 can include an odd number (e.g., 9, 19, 29, etc.) of rows of channel structures 440 arranged in a staggered manner between two adjacent GLS structures 430. It is understood that although one memory finger 435 is illustrated in FIG. 4, multiple memory fingers 435 may be included in 3D memory device 400, for example. In some implementations, a first portion 431 of the GLS structure 430 in the core array region 410 has a first width in the bit line direction (i.e., Y-direction), and a second portion 432 of the GLS structure 430 in the word line pick-up region 420 has a second width in the bit line direction (i.e., Y-direction) different from the first width. For example, as shown in FIG. 4, the first width of the first portion 431 of the GLS structure 430 is less than the second width of the second portion 432 of the GLS structure 430.

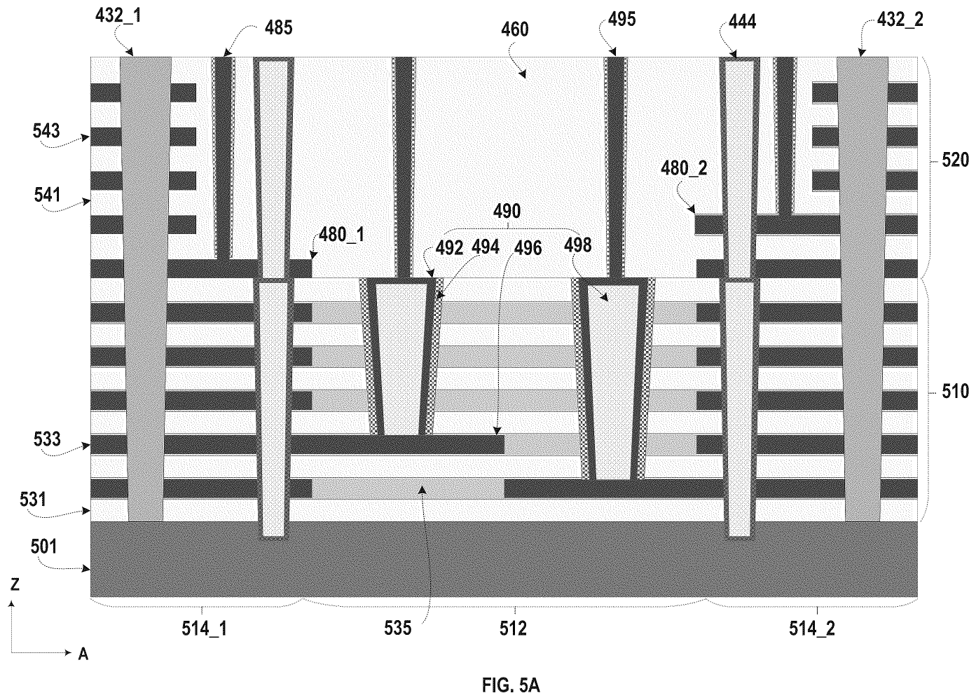

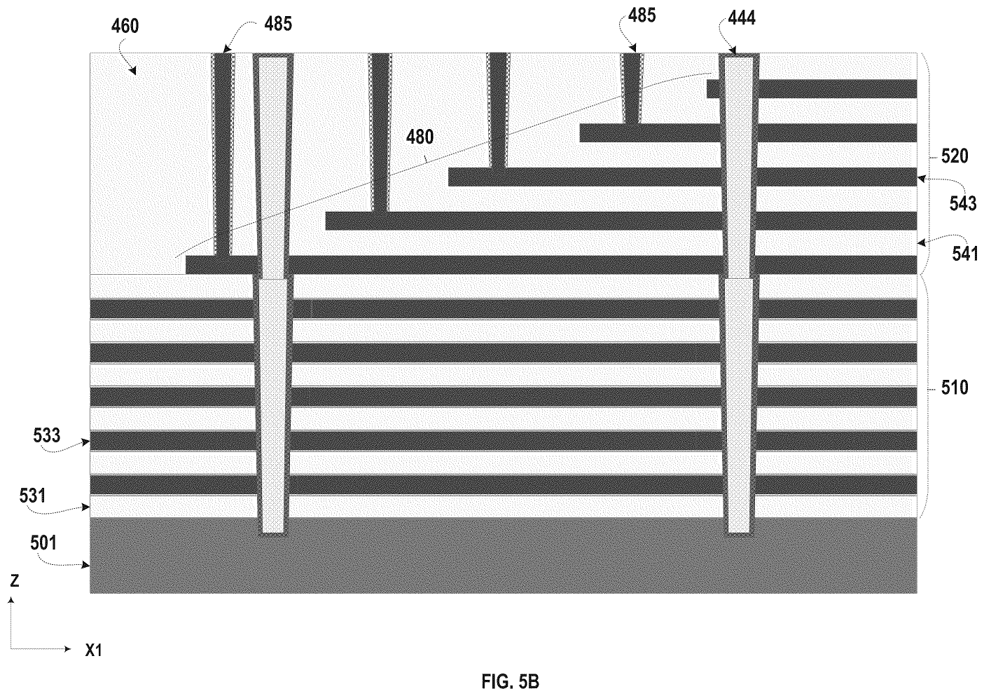

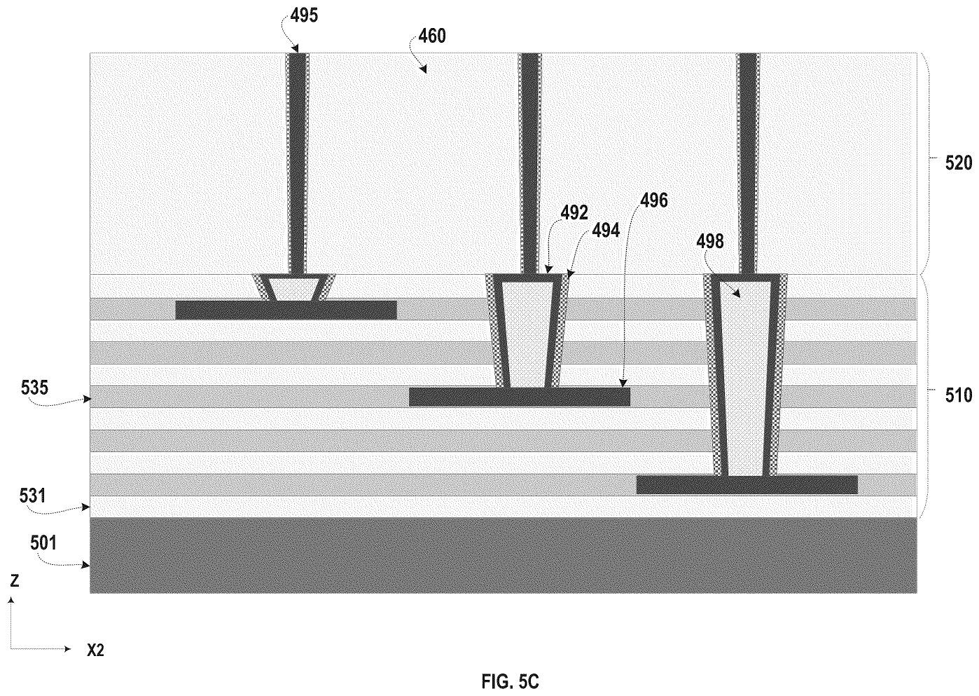

The word line pick-up region 420 is described below in detail in connection with FIGS. 4 and 5A-5C. FIG. 5A illustrates a cross-sectional view of the word line pick-up region 420 along the AA′ line of the 3D memory device 400 shown in FIG. 4, according to various implementations of the present disclosure. FIG. 5B illustrates a cross-sectional view of the word line pick-up region 420 along the X1X1′ line of the 3D memory device 400 shown in FIG. 4, according to various implementations of the present disclosure. FIG. 5C illustrates a cross-sectional view of the word line pick-up region 420 along the X2X2′ line of the 3D memory device 400 shown in FIG. 4, according to various implementations of the present disclosure. As shown in FIGS. 5A-5C, the word line pick-up region 420 can include a lower structure 510 on a substrate 501, and an upper structure 520 on the lower structure 510.

In some implementations, the substrate 501 can include silicon (e.g., single crystalline silicon), silicon germanium (SiGe), gallium arsenide (GaAs), germanium (Ge), silicon on insulator (SOI), or any other suitable materials. In some implementations, substrate 501 includes single crystalline silicon, which is part of the wafer on which 3D memory device 400 is fabricated, either in its native thickness or being thinned. In some implementations, substrate 501 includes, for example, polysilicon, which is a semiconductor layer replacing the part of the wafer on which 3D memory device 400 is fabricated.

It is noted that the X, Y, Z, A, X1, and X2 axes are included in FIGS. 4 and 5A-5C to further illustrate the spatial relationship of the components in 3D memory device 400. Substrate 501 of 3D memory device 400 includes two lateral surfaces extending laterally in the X-Y plane: a top surface on the front side of the wafer on which the lower structure 510 can be formed, and a bottom surface on the backside opposite to the front side of the wafer. The Z-axis and the A-axis are perpendicular to both the X and Y axes. The A-axis is along the AA′ line shown in FIG. 4, the X1-axis is along the X1X1′ line shown in FIG. 4, the X2-axis is along the X2X2′ line shown in FIG. 4. As used herein, whether one component (e.g., a layer or a device) is “on,” “above,” or “below” another component (e.g., a layer or a device) of 3D memory device 400 is determined relative to substrate 501 of 3D memory device 400 in the Z-direction (the vertical direction perpendicular to the X-Y plane) when substrate 501 is positioned in the lowest plane of 3D memory device 400 in the Z-direction. The same notion for describing the spatial relationship is applied throughout the present disclosure.

The lower structure 510 comprises one or more first stacks 514 and a second stack 512 on a lateral side of the one or more first stacks 514. The first stack 514 can comprise interleaved lower conductive layers 533 and first lower dielectric layers 531. The second stack 512 can comprise interleaved second lower dielectric layers 535 and the first lower dielectric layers 531. The material of the second lower dielectric layers 535 is different from the material of the first lower dielectric layers 531. In some implementations, as shown in FIG. 5, the first stack 514 comprises a first portion 514_1 adjacent to the first slit structure 432_1, and a second portion 514_2 adjacent to the second slit structure 432_2. The second stack 512 is located between the first portion 514_1 and the second portion 514_2 of the first stack 514 along the bit line direction (i.e., Y-direction).

In some implementations, each lower conductive layer 533 in the first stack 514 of word line pick-up region 420 functions as a gate line of the lower portion of the NAND memory strings (in the forms of channel structures 440) in core array region 410, as well as a word line extending laterally from the gate line and ending in the first stack 514 of word line pick-up region 420 for word line pick-up/fan-out through lower contact structures 490. The word lines (i.e., the conductive layers 533) at different depths/level of the lower structure 510 each extends laterally in core array region 410 and first stack 514 of word line pick-up region 420, but are discontinuous (e.g., being replaced by the second dielectric layers) at the second stack 512 of word line pick-up region 420, according to some implementations.

In some implementations, as shown in FIGS. 5A and 5C, lower contact structures 490 extend vertically in the second stack 512 (the dielectric stack structure in the word line pick-up region 420) at different depths in the Z-direction. In some implementations, each lower contact structure 490 includes a vertical conductive structure 492, and a lateral conductive structure 496 below and in contact with the vertical conductive structure 492. The vertical conductive structure 492 and the lateral conductive structure 496 can include conductive materials including, but not limited to, W, Co, Cu, Al, TiN, polysilicon, doped silicon, silicides, or any combination thereof.

Optionally, in some implementations as shown in FIGS. 5A and 5C, each lower contact structure 490 further includes a spacer layer 494 circumscribing the vertical conductive structure 492. The spacer layer 494 can include dielectric materials including, but not limited to, silicon oxide, silicon nitride, silicon oxynitride, or any combination thereof. Optionally, in some implementations as shown in FIGS. 5A and 5C, each lower contact structure 490 further includes a filling layer 498 surrounded by the vertical conductive structure 492 and the lateral conductive structure 496. The filling layer 498 can include dielectric materials, including, but not limited to, silicon oxide, silicon nitride, silicon oxynitride, or any combination thereof. In some implementations, the vertical conductive structure 492 and the lateral conductive structure 496 include TiN/W, and the spacer layer 494 and the filling layer 498 include silicon oxide.

It is noted that, the top surfaces of different lower contact structures 490 can be flush with one another, while the bottom surfaces of different lower contact structures 490 can extend to different levels, for example, different second lower dielectric layers 535 of lower structure 510. In some implementations, the lateral conductive structure 496 can be laterally in contact with the corresponding one of the lower conductive layers 533 of the first stack 514. As shown in FIG. 4, in some implementations, the lower contact structures 490 in each memory finger 435 can be arranged as two rows each aligned along the word line direction (i.e., X-direction) between the first slit structure 432_1 and the second slit structure 432_2. In some implementations, the two rows of the lower contact structures 490 are arranged in a staggered manner in the bit line direction (i.e., Y-direction). A first row of the lower contact structures 490 are located adjacent to the first portion 514_1 of the first stack 514, and a second row of the lower contact structures 490 are located adjacent to the second portion 514_2 of the first stack 514. In some implementations, each lower contact structure 490 in the first row is in contact with a corresponding odd layer of the lower conductive layers 533 in the first portion 514_1 of the first stack 514, and each lower contact structure 490 in the second row is in contact with a corresponding even layer of the lower conductive layers 533 in the second portion 514_2 of the first stack 514.

As shown in FIGS. 4 and 5A-5B, the upper structure 520 comprises a staircase structure 480 comprising interleaved upper conductive layers 543 and upper dielectric layers 541. The staircase structure 480 of the upper structure 520 is located on the first stack 514 of the lower structure 510. In some implementations, the staircase structure 480 can include a first staircase 480_1 adjacent to the first slit structure 432_1 and on the first portion 514_1 of the first stack 514. The staircase structure 480 can further include a second staircase 4802 adjacent to the second slit structure 432_2 and on the second portion 514_2 of the first stack 514. In some implementations, the first staircase 480_1 comprises odd numbers of stairs, and the second staircase 480_2 comprises even numbers of stairs. A dielectric filling structure 460 is located above and between the first staircase 480_1 and the second staircase 480_2.

In some implementations, the lower conductive layers 533 and the upper conductive layers 543 can include conductive materials including, but not limited to, W, Co, Cu, Al, TiN, polysilicon, doped silicon, silicides, or any combination thereof. The first lower dielectric layers 531, the second lower dielectric layers 535, the upper dielectric layers 541, and the dielectric filling structure 460 can include dielectric materials including, but not limited to, silicon oxide, silicon nitride, silicon oxynitride, or any combination thereof. The first lower dielectric layers 531 and the second lower dielectric layers 535 can have different dielectric materials, such as silicon oxide and silicon nitride. In some implementations, the lower conductive layers 533 and the upper conductive layers 543 include TiN/W, the second lower dielectric layers 535 include silicon nitride, and the first lower dielectric layers 531, the upper dielectric layers 541, and the dielectric filling structure 460 include silicon oxide.

In some implementations, each upper conductive layer 543 in the staircase structure 480 functions as a gate line of the upper portion of the NAND memory strings (in the forms of channel structures 440) in core array region 410, as well as a word line extending laterally from the gate line and ending in the staircase structure 480 of word line pick-up region 420 for word line pick-up/fan-out through stair contacts 485. The word lines (i.e., the upper conductive layers 543) at different depths/level of the upper structure 520 each extends laterally in core array region 410 and respective stair of the staircase structure 480 in the word line pick-up region 420, but are discontinuous (e.g., being replaced by the second dielectric layers) at the dielectric filling structure 460 of word line pick-up region 420, according to some implementations.

As shown in FIGS. 5A-5B, stair contacts 485 extend vertically in the dielectric filling structure 460 above the staircase structure 480 at different depths in the Z-direction and landing on the corresponding upper conductive layers 543 of the different stairs of the staircase structure 480, according to some implementations. Further, in some implementations, upper contact structures 495 extend vertically in the dielectric filling structure 460 above the second stack 512 of the lower structure 510 at the same depth in the Z-direction and landing on the corresponding lower contact structure 490. In some implementations, each stair contact 485 and each upper contact structure 495 include a vertical conductive structure and an optional spacer layer circumscribing the vertical conductive structure. The vertical conductive structure can include conductive materials including, but not limited to, W, Co, Cu, Al, TiN, polysilicon, doped silicon, silicides, or any combination thereof. The spacer layer can include dielectric materials including, but not limited to, silicon oxide, silicon nitride, silicon oxynitride, or any combination thereof.

It is noted that, the top surfaces of different stair contacts 485 can be flush with one another, while the bottom surfaces of different stair contacts 485 can extend to different levels, for example, different upper conductive layers 543 of the corresponding stairs of the staircase structure 480. It is also noted that, top surfaces of different upper contact structures 495 can be flush with one another, while the bottom surfaces of different upper contact structures 495 can be flush with one another and in contact with the top surfaces of the lower contact structures 490. Accordingly, the word lines at different levels in the upper structure 520 can be electrically connected to different stair contacts 485 extending at different depths, to achieve word line pick-up/fan-out. The word lines at different levels in the lower structure 510 can be electrically connected to different pairs of upper contact structure 495 and lower contact structure 490 extending at different depths, to achieve word line pick-up/fan-out.

As shown in FIGS. 4 and 5A-5B, dummy channel structures 444 extend through the upper structure 520 and the lower structure 510 to provide mechanical support and/or load balancing, according to some implementations. In some implementations, dummy channel structure 444 has the same structure as channel structure 440, because they are formed in the same fabrication process. Dummy channel structure 444, however, cannot perform the same memory functions as channel structure 440, at least because dummy channel structures 444 are not in contact with any local contact structures (e.g., channel contacts) in the local contact layer to pick-up/fan-out dummy channel structures 444, according to some implementations. It is understood that in some examples, dummy channel structures 444 and channel structure 440 may have different structures and may be formed in different fabrication processes. For example, dummy channel structures 444 may be filled with dielectric material(s) without semiconductor materials. Nevertheless, both dummy channel structures 444 and channel structures 440 can perform the mechanical supporting functions, in particular, during the gate replacement process, as described below in detail with respect to the fabrication processes.

It is understood that, 3D memory device 400 can include any other suitable components not shown in FIGS. 4 and 5A-5C. It is also understood that the layout and arrangement of different components, such as staircase structure 480, stair contacts 485, upper contact structures 495, lower contact structure 490, dummy channel structures 444, and channel structure 440, may vary in different examples.

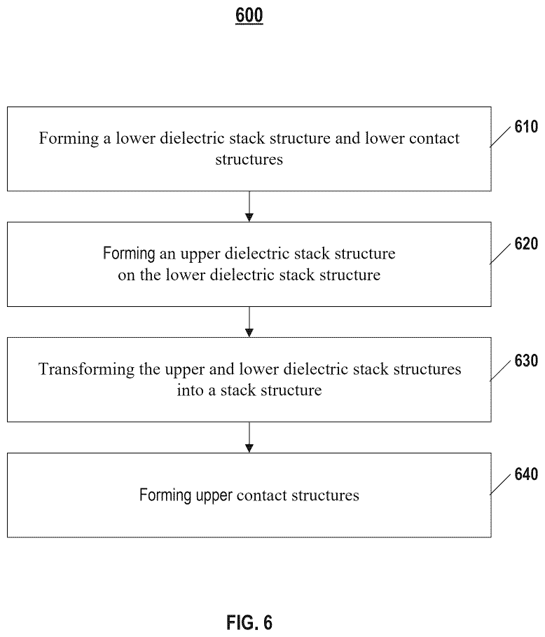

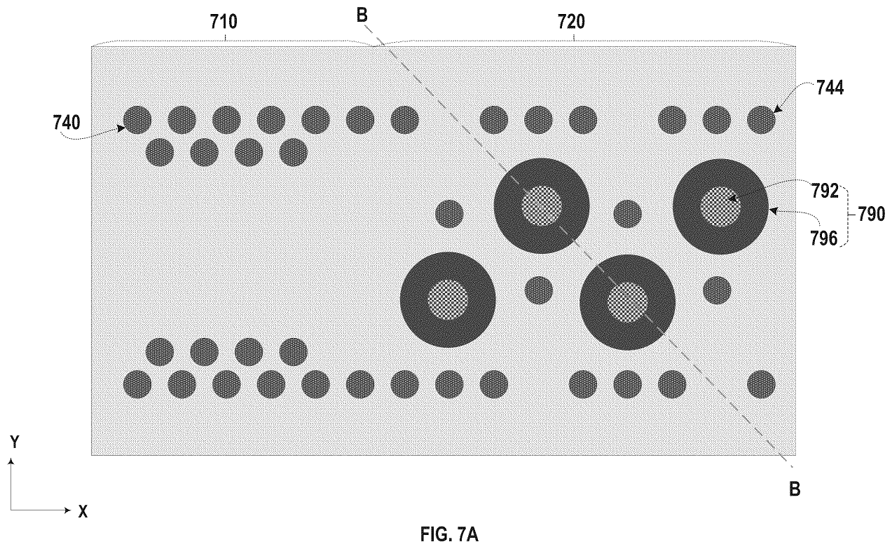

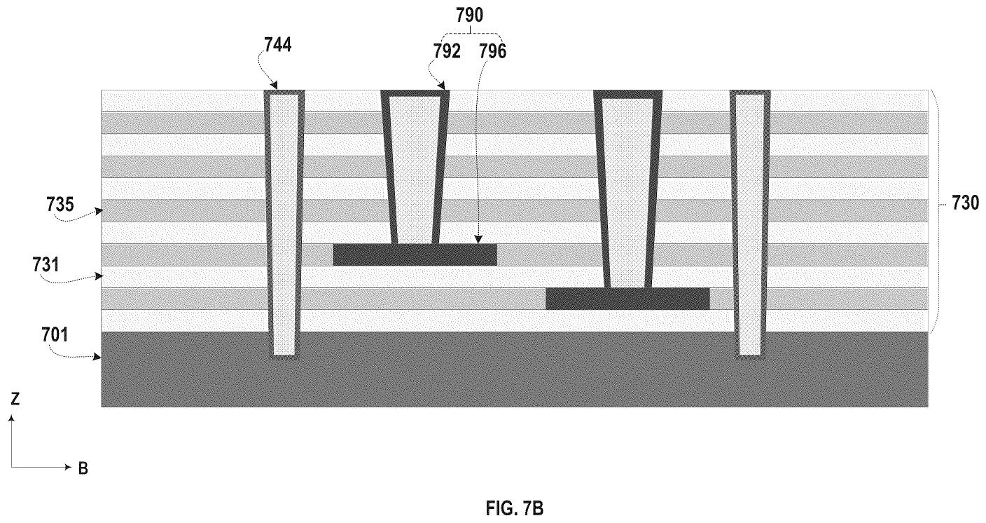

Referring to FIG. 6, a flow diagram of a method 600 for forming a 3D memory device is shown in accordance with some implementations of the present disclosure. FIGS. 7A-7B, 8A-8B, 9A-9B, and 10A-10B illustrate schematics of a 3D memory device at certain fabricating stages of the method shown in FIG. 6 in a cross-sectional view according to various implementations of the present disclosure. It is understood that the operations shown in method 600 are not exhaustive and that other operations can be performed as well before, after, or between any of the illustrated operations. Further, some of the operations may be performed simultaneously, or in a different order than shown in FIG. 6.

As shown in FIG. 6, the method can start at operation 610, in which a lower structure can be formed on a substrate. In some implementations, forming the lower structure can include forming a lower dielectric stack structure comprising interleaved first lower dielectric layers and second lower dielectric layers, forming lower channel structures and lower dummy channel structures in the lower dielectric stack structure, and forming lower contact structures. FIG. 7A illustrates a planar view of the 3D structure after operation 610, according to some implementations of the present disclosure. FIG. 7B illustrates a cross-sectional view of the 3D structure after operation 610 along the BB′ line shown in FIG. 7A, according to some implementations of the present disclosure.

As shown in FIG. 7B, a lower dielectric stack structure 730 including interleaved first lower dielectric layers 731 and second lower dielectric layers 735 is formed on a substrate 701. In some implementations, the substrate 701 can be any suitable semiconductor substrate having any suitable structure, such as a monocrystalline single-layer substrate, a polycrystalline silicon (polysilicon) single-layer substrate, a polysilicon and metal multi-layer substrate, etc.

The lower dielectric stack structure 730 including a plurality of lower dielectric layer pairs can be formed on the substrate 701. The lower dielectric stack structure 730 can include an alternating stack of a first lower dielectric layer 731 (e.g., silicon oxide) and a second lower dielectric layer 735 (e.g., silicon nitride) that is different from first lower dielectric layer 731, for example. The plurality of first lower dielectric layers 731 and second lower dielectric layers 735 are extended in a lateral direction that is parallel to the surface of the substrate 701. In some implementations, there are more layers than the lower dielectric layer pairs made of different materials and with different thicknesses in the lower dielectric stack structure 730. The lower dielectric stack structure 730 can be formed by one or more thin film deposition processes including, but not limited to, Chemical Vapor Deposition (CVD), Physical Vapor Deposition (PVD), Atomic Layer Deposition (ALD), or any combination thereof.

In some implementations, the lower dielectric stack structure 730 can include a plurality of silicon oxide/nitride layer pairs. Each dielectric layer pair includes a layer of silicon oxide 731 and a layer of silicon nitride 735. The plurality of oxide/nitride layer pairs are also referred to herein as an “alternating oxide/nitride stack.” That is, in the lower dielectric stack structure 730, multiple oxide layers 731 (shown in the areas with solid gray) and multiple nitride layers 735 (shown in the areas with meshes) alternate in a vertical direction. In other words, except a top and a bottom layer of a given alternating oxide/nitride stack, each of the other oxide layers 731 can be sandwiched by two adjacent nitride layers 735, and each of the nitride layers 735 can be sandwiched by two adjacent oxide layers 731.

Oxide layers can each have the same thickness or have different thicknesses. For example, the thickness of each oxide layer can be in a range from 10 nm to 70 nm, preferably about 25 nm. Similarly, nitride layers can each have the same thickness or have different thicknesses. For example, the thickness of each nitride layer can be in a range from 10 nm to 70 nm, preferably about 35 nm.

It is noted that, in the present disclosure, the oxide layers 731 and/or nitride layers 735 can include any suitable oxide materials and/or nitride materials. For example, the oxide materials can include silicides, and the element of nitride materials can include, but not limited to, tungsten (W), cobalt (Co), copper (Cu), aluminum (Al), doped silicon, silicides, or any combination thereof. In some implementations, the oxide layers can be silicon oxide layers, and the nitride layers can be silicon nitride layers.

The lower dielectric stack structure 730 can include any suitable number of layers of the oxide layers 731 and the nitride layers 735. In some implementations, the total number of layers of the oxide layers 731 and the nitride layers 735 in the lower dielectric stack structure 730 is equal to or larger than 64. That is, the number of oxide/nitride layer pairs can be equal to or larger than 32. In some implementations, the alternating oxide/nitride stack includes more oxide layers or more nitride layers with different materials and/or thicknesses than the oxide/nitride layer pair.

As shown in FIG. 7A, in some implementations, a plurality of lower channel structures 740 and lower dummy channel structures 744 can be formed in the lower dielectric stack structure 730. Each lower channel structure 740 and lower dummy channel structure 744 can vertically extend through the lower dielectric stack structure 730 into the substrate 701. In some implementations, the plurality of lower channel structures 740 can form an array form in a first region 710, which is used as a core array region. In some implementations, the array of lower channel structures 740 can include a plurality of rows of lower channel structures 740. Each row of lower channel structures 740 can be aligned along the word line direction (X-direction). Adjacent rows of lower channel structures 740 can be misaligned. In some implementations, the array of lower channel structures 740 can include a plurality of columns of lower channel structures 740. Each column of lower channel structures 740 can be aligned along the bit line direction (Y-direction). Adjacent columns of lower channel structures 740 can be misaligned. In some implementations, the lower dummy channel structures 744 can be formed in a second region, which is used as a contact region.

In some implementations, the fabricating process for forming the multiple lower channel structures 740 and lower dummy channel structure 744 can include forming multiple channel holes (not shown) penetrating the lower dielectric stack structure 730. The process of forming the multiple channel holes can include forming a hard mask layer (not shown) on the lower dielectric stack structure 730, and coating a photoresist layer (not shown) on the hard mask layer. A pattering process can be performed to pattern the hard mask layer. Using the hard mask layer as a mask, an etching process can be followed to etch the lower dielectric stack structure 730 to form the multiple channel holes. Each channel hole can completely penetrate the lower dielectric stack structure 730 and extend into the substrate 701. The etching process to form the multiple channel holes can be a dry etching, a wet etching, or a combination thereof. After the etching process, the photoresist layer and the hard mask layer can be removed.

In some implementations, a cleaning process can be performed to clean the multiple channel holes. The cleaning process can be a plasma ashing process including a high-temperature ashing, and/or a wet stripping. For example, a plasma source can be used to generate a reactive species, such as oxygen or fluorine. The reactive species can combine with the photoresist remaining in the channel holes to form ash, which can be removed with a vacuum pump. Specifically, in some implementations, monatomic oxygen plasma can be created by exposing oxygen gas at low pressure to high-power radio waves, which ionize the oxygen gas. The residue of the reaction between the oxygen and photoresist material can generate ash in the plasma asher. The byproducts of the ashing process, such as volatile carbon oxides and water vapor, can be pumped away with the vacuum pump within the plasma asher.

A lower channel structure 740 and/or a lower dummy channel structure 744 can be formed in each channel hole in a subsequent process. The multiple lower channel structures 740 can be arranged in a staggered array form in the first region 710, and the lower dummy channel structures 744 can be arranged in any suitable manner in the second region 720. In some implementations, each lower channel structure 740 can include an optional high-K dielectric layer (not shown), a functional layer on the sidewall of the channel hole or covering the high-K dielectric layer, a channel layer covering the functional layer, and a filling structure enclosed by the channel layer. In some implementations, the functional layer can include a barrier layer, a storage layer, and a tunneling layer. In some implementations, the lower dummy channel structure 744 can have the same structure as the lower channel structure 740.

In some implementations, fabrication processes to form the lower channel structures 740 and/or lower dummy channel structure 744 can include forming an epitaxial layer (not shown) at the bottom of each channel hole. In some implementations, the epitaxial layer can be a polycrystalline silicon (polysilicon) layer formed by using a selective epitaxial growth (SEG) process. For example, an SEG pre-clean process can be performed to clean the multiple channel holes. A following deposition process can be performed to form a polysilicon layer at the bottom of each channel hole. In some implementations, any suitable doping process, such as an ion metal plasma (IMP) process, can be performed on the polysilicon layer to form the epitaxial layer. In some implementations, the epitaxial layer may not be directly formed on the surface of the substrate 701. One or more layers can be formed between the epitaxial layer and the substrate 701. That is, the epitaxial layer overlays the substrate 701.

In some implementations, fabrication processes to form the lower channel structures 740 and/or lower dummy channel structure 744 can include forming a high-K dielectric layer (not shown) on the sidewall of each channel hole, and forming a functional layer to cover the high-K dielectric layer. The functional layer can be a composite dielectric layer, such as a combination of a barrier layer, a storage layer, and a tunneling layer. The high-K dielectric layer, the functional layer, including the barrier layer, the storage layer, and the tunneling layer, can be formed by one or more thin film deposition processes, such as ALD, CVD, PVD, any other suitable processes, or any combination thereof.

In some implementations, the barrier layer and/or the high-K dielectric layer can be formed between the storage layer and the sidewall of the channel hole. The barrier layer and/or the high-K dielectric layer can be used to block the outflow of the electronic charges. In some implementations, the barrier layer can be a silicon oxide layer or a combination of silicon oxide/silicon nitride/silicon oxide (ONO) layers. In some implementations, the high-K dielectric layer includes any suitable high dielectric constant (high k-value) dielectrics (e.g., aluminum oxide). In some implementations, the thickness of the barrier layer and/or the high-K dielectric layer can be in a range from about 3 nm to about 20 nm.

The storage layer can be formed between the tunneling layer and the barrier layer. Electrons or holes from the channel layer can tunnel to the storage layer through the tunneling layer. The storage layer can be used for storing electronic charges (electrons or holes) for memory operation. The storage or removal of charge in the storage layer can impact the on/off state and/or conductance of the semiconductor channel. The storage layer can include one or more films of materials including, but are not limited to, silicon nitride, silicon oxynitride, a combination of silicon oxide and silicon nitride, or any combination thereof. In some implementations, the storage layer can include a nitride layer formed by using one or more deposition processes. In some implementations, the thickness of the storage layer can be in a range from about 3 nm to about 20 nm.

The tunneling layer can be formed on the sidewall of the storage layer. The tunneling layer can be used for tunneling electronic charges (electrons or holes). The tunneling layer can include dielectric materials including, but not limited to, silicon oxide, silicon nitride, silicon oxynitride, or any combination thereof. In some implementations, the tunneling layer can be an oxide layer formed by using a deposition process. In some implementations, the thickness of the tunneling layer can be in a range from about 3 nm to about 20 nm.

In some implementations, fabrication processes to form the lower channel structures 740 and/or lower dummy channel structure 744 further include forming a channel layer covering the sidewall of the functional layer. In some implementations, the channel layer can be an amorphous silicon layer or a polysilicon layer formed by using a thin film deposition process, such as ALD, CVD, PVD, or any other suitable process. In some implementations, the thickness of the channel layer can be in a range from about 5 nm to 20 nm.

In some implementations, fabrication processes to form the lower channel structures 740 and/or lower dummy channel structure 744 further include forming a filling structure to cover the channel layer and fill the channel hole. In some implementations, the filling structure can be an oxide layer formed by using any suitable deposition process, such as ALD, CVD, PVD, etc. In some implementations, the filling structure can include one or more airgaps (not shown).

As shown in FIGS. 7A and 7B, operation 610 further comprises forming a plurality of lower contact structures 790 in the second region 720. In some implementations, the lower contact structures 790 can be formed to extend vertically in the second region 720 of the lower dielectric stack structure 730. In some implementations, different lower contact structures 790 can be formed to have different depths in the Z-direction. In some implementations, each lower contact structure 790 can be formed to include a vertical conductive structure 792, and a lateral conductive structure 796 below and in contact with the vertical conductive structure 792. The vertical conductive structure 792 and the lateral conductive structure 796 can include conductive materials including, but not limited to, W, Co, Cu, Al, TiN, polysilicon, doped silicon, silicides, or any combination thereof.

In some implementations, each lower contact structure 790 can be formed to further include a spacer layer circumscribing the vertical conductive structure 792. The spacer layer can include dielectric materials including, but not limited to, silicon oxide, silicon nitride, silicon oxynitride, or any combination thereof. In some implementations, each lower contact structure 790 can be formed to further include a filling layer surrounded by the vertical conductive structure 792 and the lateral conductive structure 796. The filling layer can include dielectric materials, including, but not limited to, silicon oxide, silicon nitride, silicon oxynitride, or any combination thereof. In some implementations, the vertical conductive structure 792 and the lateral conductive structure 796 include TiN/W, and the spacer layer and the filling layer include silicon oxide.

In some implementations, forming the plurality of lower contact structures 790 can include the following steps. First, multiple openings each extending into a part of the lower dielectric stack structure 730 including the interleaved first lower dielectric layers 731 and the second lower dielectric layers 735 are formed at different depths to expose respective ones of second lower dielectric layers 735. In some implementations, the multiple openings extend vertically through different numbers of pairs of first and second dielectric layers 731 and 735 of the lower dielectric stack structure 730, stopping at different depths to expose different second lower dielectric layers 735.

The multiple openings can be formed using a chopping process. As used herein, a “chopping” process is a process that increases the depth of one or more openings extending through the lower dielectric stack structure 730 by a plurality of etching cycles. Each etch cycle can include one or more dry etch and/or wet etch processes that etch one pair of first and second dielectric layers 731 and 735, i.e., reducing the depth by one dielectric layer pair. The purpose of the chopping process is to make the openings at different depths. Accordingly, depending on the number of openings, a certain number of chopping processes, along with a number of chopping masks, may be needed. It is understood that the number of chopping masks, the sequence of the chopping masks, the design (e.g., the number and pattern of openings) of each chopping mask, and/or the reduced depth by each chopping process (e.g., the number of etching cycles) may affect the specific depth of each opening after the chopping process.

In some implementations, a spacer layer is formed on the sidewalls and a bottom of each of the openings, thereby covering first lower dielectric layers 731 and second lower dielectric layers 735 exposed from the sidewalls of the openings. In some implementations, the spacer layer is formed by depositing dielectric materials, such as silicon oxide, using one or more thin film deposition processes, such as ALD, CVD, PVD, any other suitable processes, or any combination thereof, over the sidewalls and the bottom surfaces of the openings. In some implementations, the spacer layer on the bottom of each of the openings is removed, for example, by dry etching, to expose the respective part of the second lower dielectric layer 735. In some implementations, the etching rate, direction, and/or duration of Reactive Ion Etching (RIE) are controlled to etch only the part of the spacer layer on the bottom surface, but not on the sidewalls, of the openings, i.e., “punching” through the spacer layer in the Z-direction to expose only a corresponding second lower dielectric layer 735 from the bottom, but not other second lower dielectric layers 735 from the sidewalls.

To form the lower contact structures 790, parts of the second lower dielectric layers 735 in the second region 720 of the lower dielectric stack structure 730 can be replaced with the lateral conductive structure 796, respectively, through the openings. For example, at least a part of a corresponding exposed second lower dielectric layer 735 can be removed through each opening, by wet etching, to form a lateral recess. In some implementations, the etchant can include phosphoric acid for etching second lower dielectric layer 735 including silicon nitride. The etching rate and/or etching time for the wet etching process can be controlled to control the amount of the removal of the second lower dielectric layer 735, thereby controlling the lateral size of the formed lateral recess. The lateral conductive structure 796 can be formed in the lateral recess by depositing a conductive material through the opening. The conductive material, such as a metal material, can be deposited using one or more thin film deposition processes, such as ALD, CVD, PVD, any other suitable processes, or any combination thereof, to fill the lateral recess to form the lateral conductive structure 796.

In some implementations, vertical conductive structures 792 are formed in the openings in contact with the lateral conductive structures 796, respectively. In some implementations, the vertical conductive structures 792 can be formed in the same process as forming the lateral conductive structures 796 by depositing the conductive material not only into the lateral recesses, but also on the sidewalls and the bottom surface of openings, using one or more thin film deposition processes, such as ALD, CVD, PVD, any other suitable processes, or any combination thereof. In some implementations, a filling structure can be formed in the vertical conductive structures 792 by depositing a dielectric material.

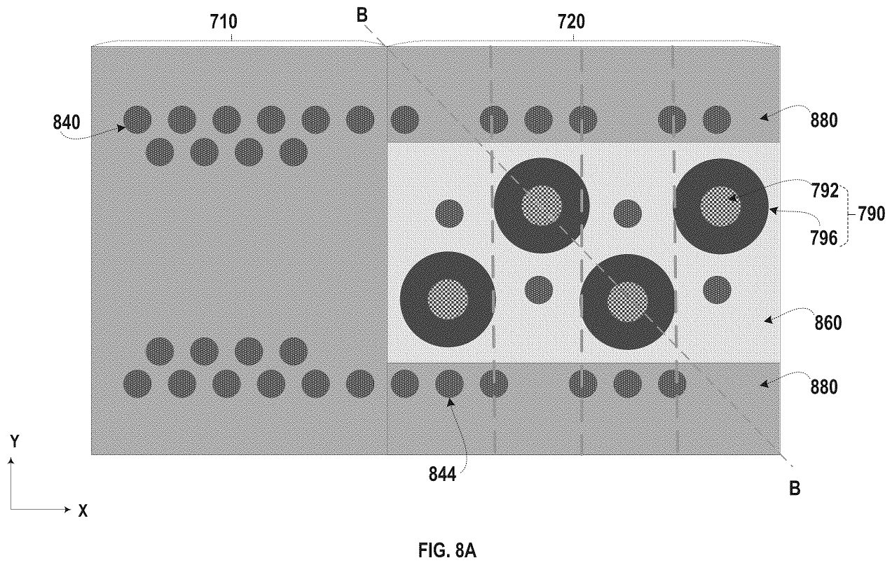

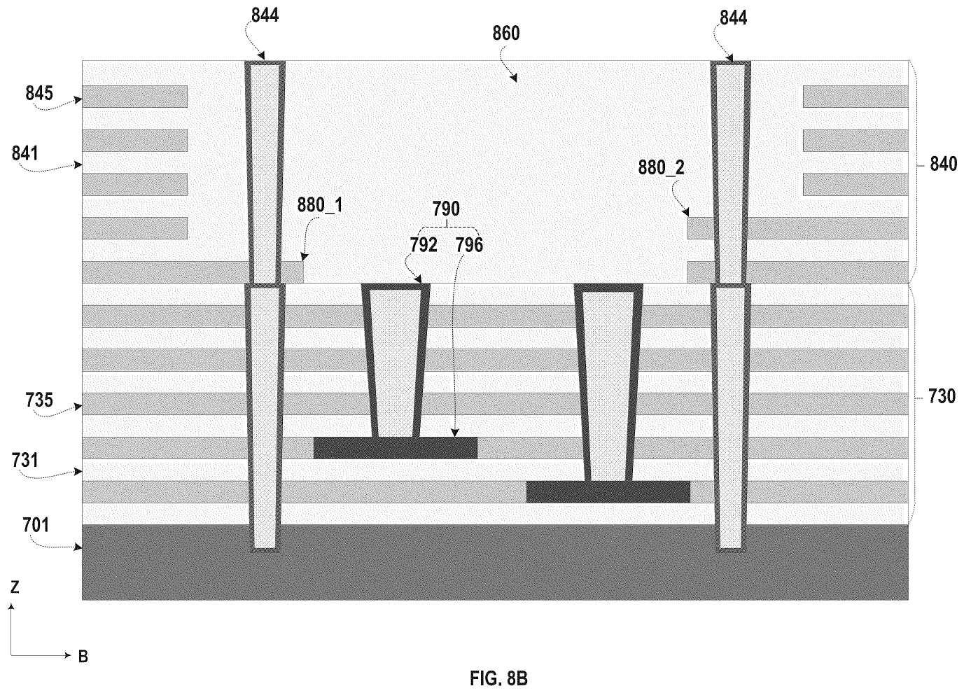

Referring back FIG. 6, the method can proceed to operation 620, in which an upper structure can be formed on the lower structure. In some implementations, forming the upper structure can include forming an upper lower dielectric stack structure comprising interleaved first upper dielectric layers and second upper dielectric layers, forming upper channel structures and upper dummy channel structures in the upper dielectric stack structure, and forming staircase structures. FIG. 8A illustrates a planar view of the 3D structure after operation 620, according to some implementations of the present disclosure. FIG. 8B illustrates a cross-sectional view of the 3D structure after operation 620 along the BB′ line shown in FIG. 8A, according to some implementations of the present disclosure.

As shown in FIG. 8B, an upper dielectric stack structure 840 including interleaved first upper dielectric layers 841 and second upper dielectric layers 845 is formed on the lower dielectric stack structure 730. In some implementations, the fabricating process of the upper dielectric stack structure 840 is similar to the fabricating process of the lower dielectric stack structure 730, as described above, and thus not repeated here. Further, a plurality of upper channel structures and upper dummy channel structures can be formed in the upper dielectric stack structure 840. Each upper channel structure and upper dummy channel structure can vertically extend through the upper dielectric stack structure 840 and be in contact with a corresponding lower channel structure 740 or lower dummy channel structure 744, respectively. In some implementations, the fabricating process of the upper channel structures and upper dummy channel structures is similar to the fabricating process of the lower channel structures 740 and lower dummy channel structures 744, as described above, and thus not repeated here. Each upper channel structure and the corresponding lower channel structure form a channel structure 844, and each upper dummy upper channel structure and the corresponding lower dummy channel structure form a dummy channel structure 844.

As shown in FIGS. 8A and 8B, portions of the upper dielectric stack structure 840 can be removed to form staircase structure 880. In some implementations, staircase structure 880 can be formed in the second region 720 of the upper dielectric stack structure 840. The staircase structure 880 can be formed by performing a plurality of so-called “trim-etch” cycles to the upper dielectric layer pairs of upper dielectric stack structure 840 toward lower dielectric stack structure 730. Due to the repeated trim-etch cycles applied to the upper dielectric layer pairs of upper dielectric stack structure 840, the upper dielectric stack structure 840 can have one or more tilted edges and a top upper dielectric layer pair shorter than the bottom one along the word line direction (i.e., X-direction).

In some implementations, the staircase structure 880 can be formed as two portions including a first staircase 880_1 comprising odd numbers of stairs, and a second staircase 880_2 comprising even numbers of stairs. A portion of the upper dielectric stack structure 840 between the first staircase 880_1 and the second staircase 880_2 in the bit line direction (i.e., Y-direction) can be completely removed. A dielectric filling structure 860 can be formed to cover the first staircase 880_1 and the second staircase 8802, and to fill the space between the first staircase 880_1 and the second staircase 880_2. A CMP process can be performed to planarize the top surface of the dielectric filling structure 860.

Referring back to FIG. 6, the method proceeds to operation 630, in which multiple gate line slits (GLSs) can be formed in the dielectric stack structure, the upper and lower dielectric stack structures can be transformed into a stack structure including multiple conductive/dielectric layer pairs, and GLS structures can be formed in the GLSs. FIG. 9A illustrates a planar view of the 3D structure after operation 630, according to some implementations of the present disclosure. FIG. 9B illustrates a cross-sectional view of the 3D structure after operation 630 along the BB′ line shown in FIG. 9A, according to some implementations of the present disclosure.

In some implementations, the gate line slits (GLSs) can be formed to extend laterally in a straight line along the word line direction (i.e., X-direction) between two arrays of channel structures 844, and vertically through the upper dielectric stack structure 840 and the lower dielectric stack structure 730 into the substrate 701. The multiple GLSs can be formed by forming a mask layer over the upper dielectric stack structure 840 and patterning the mask using, e.g., photolithography, to form openings corresponding to the multiple GLSs in the patterned mask layer. A suitable etching process, e.g., dry etch and/or wet etch, can be performed to remove portions of the upper dielectric stack structure 840 and the lower dielectric stack structure 730 exposed by the openings until the multiple GLSs expose the substrate 701. The mask layer can be removed after the formation of the multiple GLSs.

In some implementations, a gate replacement process (also known as the “word line replacement” process) can be performed to replace the second upper dielectric layers 845 of the upper dielectric stack structure 840 with upper conductive layers 945, and to replace portions of the second lower dielectric layers 735 of the lower dielectric stack structure 730 with lower conductive layers 935. In some implementations, after forming the multiple GLSs, the second upper dielectric layers 845 of the upper dielectric stack structure 840 and portions of the second lower dielectric layers 735 of the lower dielectric stack structure 730 can be removed through the GLSs to form multiple lateral trenches. The multiple lateral trenches can extend in a lateral direction, and can be used as spaces for conductive layers to be formed in a subsequent process.

The second upper dielectric layers 845 and portions of the second lower dielectric layers 735 are used as sacrificial layers, and are removed by using any suitable etching process, e.g., an isotropic dry etch or a wet etch. The etching process can have sufficiently high etching selectivity of the material of the second upper dielectric layers 845 and the second lower dielectric layers 735 over the materials of the first upper dielectric layer 841 and the first lower dielectric layer 731, such that the etching process can have minimal impact on the first upper dielectric layer 841 and the first lower dielectric layer 731. The isotropic dry etch and/or the wet etch and a following cleaning process can remove second upper dielectric layers 845 and portions of the second lower dielectric layers 735 in various directions to expose the top and bottom surfaces of each first upper dielectric layer 841 and the first lower dielectric layer 731. As such, multiple lateral trenches can then be formed between adjacent first upper dielectric layers 841 and adjacent first lower dielectric layers 731.

In some implementations, the etchant can include phosphoric acid for etching the second upper dielectric layers 845 and portions of the second lower dielectric layers 735 including silicon nitride. The etching rate and/or etching time for the wet etching process can be controlled to control the amount of the removal of the second lower dielectric layer 735, thereby exposing the lateral conductive structures 796. The remaining portions of the second lower dielectric layers 735 are located under the dielectric filling structure 860 and laterally surrounding the vertical conductive structures 792.

As shown in FIG. 9B, multiple upper conductive layers 945 and lower conductive layers 935 can be formed in the multiple lateral trenches. The multiple upper conductive layers 945 and lower conductive layers 935 can be used as word lines (i.e., gate electrodes) in the 3D memory device. In some implementations, each upper conductive layer 945 and lower conductive layers 935 can be coated with one or more insulating layers (not shown) used as gate dielectric layers for insulating the respective word line (i.e., gate electrode).

In some implementations, one or more insulating layers (not shown) can be formed in each of the multiple lateral trenches to cover the exposed surfaces of the lateral trenches with one or more suitable insulating materials. For example, one or more suitable deposition processes, such as CVD, PVD, and/or ALD, can be utilized to deposit the one or more insulating materials into the lateral trenches. In some implementations, a recess etch and/or a chemical-mechanical planarization (CMP) can be used to remove excessive insulating material(s). The one or more insulating materials can include any suitable materials (e.g., high k-value dielectrics) that provide an electric insulating function. For example, the one or more insulating materials can include silicon oxide, silicon nitride, silicon oxynitride, aluminum oxide, titanium nitride, etc., and/or any suitable combinations thereof. In some implementations, multiple insulating layers can have different insulating materials.

An upper conductive layers 945 or a lower conductive layers 935 can be formed in each lateral trench between the one or more insulating layers. The upper conductive layers 945 and lower conductive layers 935 can be formed by filling the lateral trenches with a suitable conductive material, e.g., tungsten, aluminum, copper, cobalt, or any combination thereof, for forming the word lines (i.e., gate electrodes). The conductive material can be deposited into lateral trenches using a suitable deposition method such as CVD, PVD, plasma-enhanced CVD (PECVD), sputtering, metal-organic chemical vapor deposition (MOCVD), and/or ALD. In some implementations, the upper conductive layers 945 and lower conductive layers 935 include tungsten formed by CVD. As such, the upper dielectric stack structure 840 and the lower dielectric stack structure 730 is transformed into a stack structure including alternating conductive/dielectric layer pairs. Further, each lower conductive layer 935 is electrically connected to a corresponding lateral conductive structure 796 of the lower contact structure 790.

After the gate replacement process, a (GLS) structure 930 can be formed in each GLS. In some implementations, the GLS structure 930 is an insulating structure that does not include any interconnects therein (i.e., not functioning as the source contact). It can be formed by depositing one or more dielectric materials to fill the GLS. In some other implementations, the GLS structure 930 is a source contact further including a conductive portion (e.g., including W, polysilicon, and/or TiN) circumscribed by a slit spacer layer, the fabricating process for forming the GLS structure 930 can include forming a slit spacer layer (not shown) on the sidewalls of the multiple GLSs. The slit spacer layer is also referred to as a gate line spacer (GLSP) layer, and can be used to provide electrical insulation between the upper conductive layers 945 and lower conductive layers 935 and the conductive portion formed in a subsequent process.

In some implementations, the fabricating process for forming a spacer layer can include a word line gate recess process. After forming the upper conductive layers 945 and lower conductive layers 935, portions of the upper conductive layers 945 and lower conductive layers 935 (word lines) exposed by the GLSs can be removed by a recess etching process. In some implementations, in order to ensure the insulation between the upper conductive layers 945 and lower conductive layers 935 (word lines), a recess etching process, such as a wet etching process, can be performed to remove portions of the upper conductive layers 945 and lower conductive layers 935 exposed by the GLSs. In doing so, a recess can be formed in each lateral trench adjacent to the GLSs.

In some implementations, the fabricating process for forming the GLS structure 930 can include forming a conductive portion in each GLS. The conductive portion can be in contact with a doped region (not shown) in the substrate 701, and is used as an array common source (ACS) of the multiple NAND strings. In some implementations, the conductive portion can be formed by depositing a conductive material, such as polysilicon, silicides, tungsten, aluminum, copper, and/or combinations thereof etc. The conductive material can be deposited into the multiple GLSs using a suitable deposition method such as CVD, PVD, ECVD, sputtering, MOCVD, and/or ALD.

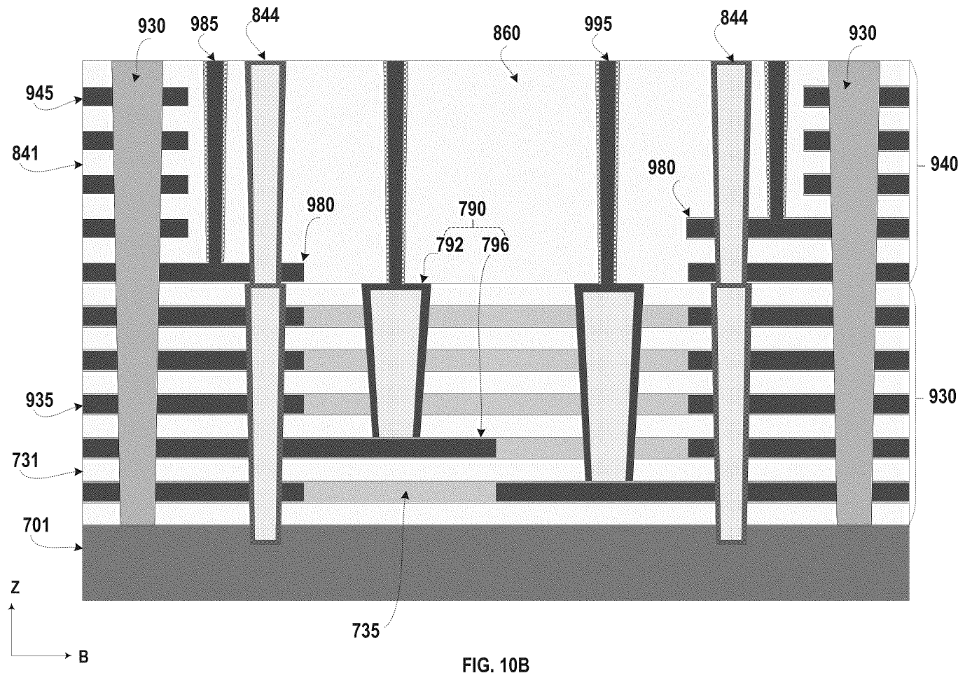

Referring back to FIG. 6, the method proceeds to operation 640, in which stair contacts and upper contact structures can be formed in the upper structure. FIG. 10A illustrates a planar view of the 3D structure after operation 640, according to some implementations of the present disclosure. FIG. 10B illustrates a cross-sectional view of the 3D structure after operation 640 along the BB′ line shown in FIG. 9A, according to some implementations of the present disclosure.

As shown in FIGS. 10A and 10B, stair contacts 985 and upper contact structures 995 can be formed each extending vertically in the dielectric filling structure 860 of the upper structure 940. The stair contacts 985 can be formed above the staircase structure 980 at different depths in the Z-direction and landing on the corresponding upper conductive layers 945 of the different stairs of the staircase structure 980. The upper contact structures 495 can be formed and extend vertically in the dielectric filling structure 860 at the same depth in the Z-direction and landing on a corresponding lower contact structure 790.

In some implementations, fabricating processes of forming the stair contacts 985 and upper contact structures 995 can include performing a suitable etching process, e.g., dry etch and/or wet etch, to remove portions of the dielectric filling structure 860 in the upper structure 940 to form contact holes. In some implementations, the contact holes can expose a corresponding upper conductive layer 945 on a stair of the staircase structure 980 or expose a top surface of a corresponding lower contact structure 790. A mask layer (not shown) can be used to control the locations and sizes of the contact holes during the etching process.

As shown in FIGS. 10A and 10B, in some implementations, a deposition process can then be performed to fill the contact holes with any suitable conductive material (e.g., W, Co, Cu, Al, TiN, polysilicon, doped silicon, silicides, etc.) to form the stair contacts 985 and upper contact structures 995. It is noted that, before depositing the conductive material, an optional spacer layer can be formed by depositing a dielectric material (e.g., silicon oxide, silicon nitride, silicon oxynitride, etc.) on sidewalls of the contact holes. A CMP process can be performed to make the top surfaces of the stair contacts 985 and upper contact structures 995 flush with one another.

It is noted that, the bottom surfaces of different stair contacts 985 are formed to extend to different levels, for example, different upper conductive layers 945 of the corresponding stairs of the staircase structure 980. It is also noted that, the bottom surfaces of different upper contact structures 995 can be flush with one another and in contact with the top surfaces of the lower contact structures 790. Accordingly, the word lines at different levels in the upper structure 940 can be electrically connected to different stair contacts 985 extending at different depths, to achieve word line pick-up/fan-out. The word lines at different levels in the lower structure 930 can be electrically connected to different pairs of upper contact structure 995 and lower contact structure 790 extending at different depths, to achieve word line pick-up/fan-out.

The foregoing description of the specific implementations will so fully reveal the general nature of the present disclosure that others can, by applying knowledge within the skill of the art, readily modify and/or adapt for various applications such specific implementations, without undue experimentation, without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Implementations of the present disclosure have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The Summary and Abstract sections may set forth one or more but not all implementations of the present disclosure as contemplated by the inventor(s), and thus, are not intended to limit the present disclosure and the appended claims in any way.

The breadth and scope of the present disclosure should not be limited by any of the above-described implementations, but should be defined only in accordance with the following claims and their equivalents.

What is claimed is:

1. A semiconductor device, comprising:
a lower structure comprising:
a first stack comprising interleaved lower conductive layers and first lower dielectric layers,
a second stack on a lateral side of the first stack, and comprising interleaved second lower dielectric layers and the first lower dielectric layers, and
lower contact structures extending in the second stack and each being in contact with a corresponding one of the lower conductive layers of the first stack; and
an upper structure on the lower structure, comprising:
a staircase structure comprising interleaved upper conductive layers and upper dielectric layers on the first stack,
a dielectric filling structure on the second stack,
stair contacts on the staircase structure, each stair contact being in contact with a corresponding one of the upper conductive layers, and
upper contact structures each extending through the dielectric filling structure and in contact with a corresponding one of the lower contact structures.

2. The semiconductor device of claim 1, wherein each lower contact structure comprises:
a vertical conductive structure vertically extending in the second stack; and
a lateral conductive structure at a bottom of the vertical conductive structure and laterally in contact with the corresponding one of the lower conductive layers of the first stack.

3. The semiconductor device of claim 2, wherein each lower contact structure further comprises:
a spacer layer laterally surrounding the vertical conductive structure to separate the vertical conductive structure from the second stack; and
a filling layer surrounded by the vertical conductive structure and the lateral conductive structure.

4. The semiconductor device of claim 1, further comprising:
a first slit structure and a second slit structure extending parallel along a first lateral direction in the upper structure and the lower structure, wherein:
the first stack comprises a first portion adjacent to the first slit structure and a second portion adjacent to the second slit structure; and
the second stack is located between the first portion and the second portion of the first stack along a second lateral direction perpendicular to the first lateral direction.

5. The semiconductor device of claim 4, wherein the staircase structure comprises:
a first staircase adjacent to the first slit structure and comprises odd numbers of stairs; and
a second staircase adjacent to the second slit structure and comprises even numbers of stairs;
wherein the dielectric filling structure is located between the first staircase and the second staircase along the second lateral direction.

6. The semiconductor device of claim 4, wherein:
the lower contact structures are aligned into two rows between the first slit structure and the second slit structure;
each of the two rows of the lower contact structures extends along the first lateral direction; and
the two rows of the lower contact structures are arranged in a staggered manner in the second lateral direction.

7. The semiconductor device of claim 4, wherein:
a first row of the lower contact structures are located adjacent to the first portion of the first stack;
each lower contact structure in the first row is in contact with a corresponding odd layer of the lower conductive layers in the first portion of the first stack;
a second row of the lower contact structures are located adjacent to the second portion of the first stack; and
each lower contact structure in the second row is in contact with a corresponding even layer of the lower conductive layers in the second portion of the first stack.

8. The semiconductor device of claim 4, further comprising:
channel structures vertically extending in the upper structure and the lower structure in an array region; and
dummy channel structures vertically extending in the upper structure and the lower structure in a contact region.

9. The semiconductor device of claim 8, wherein the first slit structure and the second slit structure have a first width along the second lateral direction in the array region and a second width different from the first width in the contact region.

10. The semiconductor device of claim 5, wherein the stair contacts comprise:
a first group of stair contacts on the first staircase and in contact with the upper conductive layers of the odd numbers of stairs; and
a second group of stair contacts on the second staircase and in contact with the upper conductive layers of the even numbers of stairs.

11. A memory system, comprising:
a memory device, comprising:
a lower structure comprising:
a first stack comprising interleaved lower conductive layers and first lower dielectric layers,
a second stack on a lateral side of the first stack, and comprising interleaved second lower dielectric layers and the first lower dielectric layers, and
lower contact structures extending in the second stack and each being in contact with a corresponding one of the lower conductive layers of the first stack; and
an upper structure on the lower structure, comprising:
a staircase structure comprising interleaved upper conductive layers and upper dielectric layers on the first stack,
a dielectric filling structure on the second stack,
stair contacts on the staircase structure, each stair contact being in contact with a corresponding one of the upper conductive layers, and
upper contact structures each extending through the dielectric filling structure and in contact with a corresponding one of the lower contact structures; and
a memory controller coupled with the memory device and configured to control the memory device.

12. A method of forming semiconductor device, comprising:
forming a lower structure comprising:
forming a first stack comprising interleaved lower conductive layers and first lower dielectric layers,
forming a second stack comprising interleaved second lower dielectric layers and the first lower dielectric layers, and
forming lower contact structures in the second stack, each lower contact structure being in contact with a corresponding one of the lower conductive layers of the first stack; and
forming an upper structure comprising:
forming interleaved upper conductive layers and upper dielectric layers on the lower structure,
forming a staircase structure on the first stack,
forming a dielectric filling structure on the second stack, and
forming upper contact structures each extending through the dielectric filling structure and in contact with a corresponding one of the lower contact structures.

13. The method of claim 12, wherein forming the upper structure further comprises:
forming stair contacts on the staircase structure, each stair contact being in contact with a corresponding one of the upper conductive layers;
wherein the stair contacts and the upper contact structures are formed simultaneously in a same process.

14. The method of claim 12, wherein forming each lower contact structure comprises:
forming an opening in the second stack and stopping at one second lower dielectric layer;
removing a portion of the at one second lower dielectric layer and forming a lateral conductive structure;
forming a spacer layer on a sidewall of the opening and the lateral conductive structure;
removing a bottom portion of the spacer layer to expose the lateral conductive structure; and
forming a vertical conductive structure in the opening and in contact with the lateral conductive structure.

15. The method of claim 14, further comprising:
forming a first slit and a second slit extending parallel along a first lateral direction and vertically in the upper structure and the lower structure; and
replacing portions of the second lower dielectric layers adjacent to the first slit and the second slit by the lower conductive layers to form the first stack.

16. The method of claim 15, wherein forming the lower contact structures comprises:
forming rows of the lower contact structures, each row of the lower contact structures extending along the first lateral direction,
wherein the rows of the lower contact structures are arranged in a staggered manner in a second lateral direction perpendicular to the first lateral direction.

17. The method of claim 16, wherein replacing portions of the second lower dielectric layers comprises:
replacing the portions of the second lower dielectric layers adjacent to the first slit to form a first portion of the first stack, such that odd layers of the lower conductive layers in the first portion are in contact with the lateral conductive structures of a first row of the lower contact structures, respectively; and
replacing the portions of the second lower dielectric layers adjacent to the second slit to form a second portion of the first stack, such that even layers of the lower conductive layers in the second portion are in contact with the lateral conductive structures of a second row of the lower contact structures.

18. The method of claim 16, further comprising:
forming channel structures vertically extending in the upper structure and the lower structure in an array region; and
forming dummy channel structures vertically extending in the upper structure and the lower structure in a contact region.

19. The method of claim 18, further comprising:
filling portions of the first slit and the second slit in the contact region;
replacing the second lower dielectric layers of the lower structure in the array region with the lower conductive layers in the array region; and
replacing upper sacrificial layers of the upper structure in the array region with the upper conductive layers in the array region.

20. The method of claim 19, further comprising:
forming a first slit structure in the first slit and a second slit structure in the second slit, wherein the first slit structure and the second slit structure have a first width along the second lateral direction in the array region and a second width different from the first width in the contact region.
